(19) United States
(12) Patent Application Publication
(10) Pub. No.: US 2025/0254819 A1
(43) Pub. Date: Aug. 7, 2025

(54) THERMAL CORRECTION FOR ENCLOSURES

(71) Applicant: Micron Technology, Inc., Boise, ID (US)

(72) Inventors: David Rodney Christianson, Meridian, ID (US); Bradley Russell Bitz, Meridian, ID (US); Steve Daniel Abrahamson, Boise, ID (US); João Elmiro Rocha Chaves, Middleton, ID (US)

(21) Appl. No.: 19/035,727

(22) Filed: Jan. 23, 2025

Related U.S. Application Data
(60) Provisional application No. 63/550,346, filed on Feb. 6, 2024.

(51) Int. Cl. H05K 7/20

(52) U.S. Cl. CPC H05K 7/20145; H05K 7/20172; H05K 7/20418; H05K 7/20736

(57) ABSTRACT

An apparatus includes an enclosure to enclose a memory sub-system within an interior of the enclosure. The memory sub-system includes a memory device and a memory sub-system controller communicably coupled to the memory device. The enclosure includes a plurality of openings exposing at least a portion of the interior of the enclosure to an environment outside the enclosure. The enclosure further includes a plurality of fins affixed to an exterior surface of the enclosure. Each fin of the plurality of fins is disposed adjacent to at least one of the openings of the plurality of openings.

### RELATED APPLICATIONS

This application claims the benefit of U.S. Provisional Patent Application No. 63/550,346, filed Feb. 6, 2024, the entire contents of which are hereby incorporated by reference herein.

### TECHNICAL FIELD

Embodiments of the disclosure relate generally to memory sub-systems, and more specifically, relate to thermal correction for enclosures, including enclosures for memory sub-systems.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices. A memory sub-system can be housed within an enclosure, that is optionally mounted on a rack, for example, as part of or with a rackmount server, optimizing space efficiency and simplifying maintenance in data centers and server environments. These enclosures often align with standardized rack dimensions, offering durable physical protection and electromagnetic shielding. Additionally, enclosures can be equipped with features for thermal management.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 illustrates an example rackmount server system that includes enclosures in accordance with some embodiments of the present disclosure.

FIG. 3A illustrates an enclosure in accordance with some embodiments of the present disclosure.

FIG. 3B illustrates a perspective view of an enclosure in accordance with some embodiments of the present disclosure.

FIG. 3C illustrates a top view of an enclosure in accordance with some embodiments of the present disclosure.

FIG. 3D illustrates a perspective of an enclosure in accordance with some embodiments of the present disclosure.

FIG. 3E illustrates top view of an enclosure in accordance with some embodiments of the present disclosure.

FIG. 3F illustrates top view of an enclosure in accordance with some embodiments of the present disclosure.

FIG. 4 is a block diagram of an example computer system in which embodiments of the present disclosure may operate.

### DETAILED DESCRIPTION

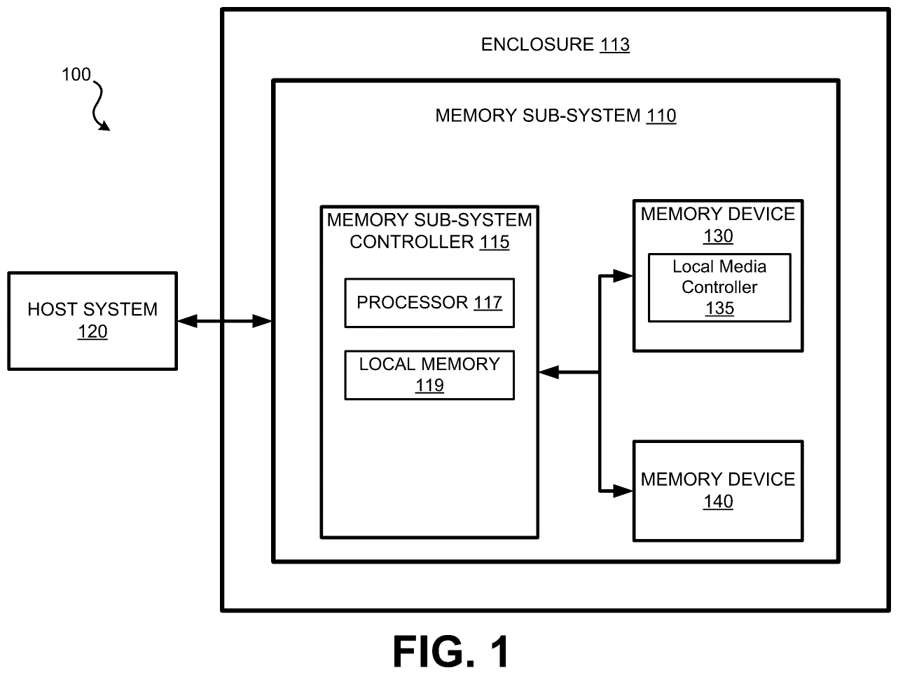

Aspects of the present disclosure are directed to thermal correction for enclosures. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

Many enclosures, such as those containing Printed Circuit Board Assemblies (PCBAs) (e.g., memory sub-systems) often utilize thermal interface materials (TIMS) and external heat sinks for thermal dissipation. These enclosures typically adhere to industry standards for dimensions, form factors, durability, etc. that allow them to be used as rackmount servers in rackmount server systems. Conventional enclosures included in rackmount servers are nearly fully sealed, creating a condition of stagnant air within. TIMs can be dispensed on enclosed PCBAs to transfer heat from the integrated circuits (ICs) of the PCBA to the interior surface of the enclosure, from where it is eventually dissipated through the enclosure to heat dissipating fins of the external heat sink. In various applications, particularly non-consumer applications, enclosed PCBAs are mounted on server chassis of rackmount servers. Fans are also mounted to the individual server chassis for cooling the rackmount servers. The rackmount servers can slot into larger server racks that can include fans for cooling the entire server system. Despite the presence of these cooling fans on the server chassis and/or the server rack, the nearly fully sealed nature of the standard-compliant enclosures leads to a reliance on TIMs and heat sinks for adequate cooling. However, these conventional thermal management solutions have limitations.

First, conventional heat sinks, attached to enclosures, may not dissipate heat swiftly enough leading to constrained performance of enclosed devices. The nearly fully closed nature of conventional enclosures can lead to stagnant air inside the enclosures that can further constrain performance, occasionally necessitating the throttling of device operations due to overheating risks. Second, the use of TIMs for heat transfer from the enclosed components to the enclosure requires specialized equipment and processing during manufacturing. This can lead to increased costs and can increase the likelihood of quality issues. Furthermore, these materials are subject to batch-to-batch inconsistencies from suppliers, leading to process control complications. Over extended periods, there is also the risk of chemical breakdown of these materials, impacting their effectiveness and stability.

Aspects of the present disclosure address the above and other deficiencies of existing technologies by providing an enclosure having openings for increased air flow and having fins affixed to the exterior surface of the enclosure that direct air flow through the interior of the enclosure. For example, a pair of fins can be disposed on either side of an opening in a surface of the enclosure to channel air flow through the opening and into an interior of the enclosure where the active circuit components are located. In one embodiment, the enclosure can be part of a rackmount server and can be mounted on a rackmount server chassis that can be slid into a server rack. Cooling fans can be mounted to the rackmount server chassis and/or to the server rack, and the air flow provided by the cooling fans can be directed by the fins through the opening(s) to the interior of the enclosure to cool enclosed components. This can be accomplished by arranging the fins and angling them in such a way that air flow provided by the cooling fans is redirected into and out of the interior of the enclosure. In one embodiment, the enclosed components can include a memory sub-system. The memory sub-system can include components such as a memory device and a memory sub-system controller communicably coupled to the memory device.

Advantages of the present disclosure include, but are not limited to, swifter dissipation of heat from enclosed components by directing air flow through the interior of the enclosure, helping to prevent limitations on device performance and potentially enhancing device performance as well. Directing air flow through the interior of the enclosure further reduces stagnant air inside the enclosure leading to enhanced performance and reduced throttling of device operations due to lack of overheating risks. Further, because components inside the enclosure are being cooled by air flow, the use of TIMs for heat transfer from the enclosed components to the enclosure can be avoided. Aspects and implementations of the present disclosure may not require specialized equipment and processing during manufacturing for the application of TIMs. Eliminating the use of TIMs can also lead to decreased costs and can decrease the likelihood of quality issues. Eliminating TIMs, which are subject to batch-to-batch inconsistencies from suppliers, can lead to reduced process control complications. Furthermore, eliminating the use of TIMs also eliminates the risk of chemical breakdown of these materials. Aspects and implementations of the present disclosure can also eliminate the need for heat sinks.

Aspects and implementations of the present disclosure can maintain compliance with industry standards for dimensions, form factors, durability, etc. that allow them to be used as rackmount servers in rackmount server systems. Further, aspects and implementations of the present disclosure leverage existing air flow from cooling fans that are mounted to rackmount servers and/or server racks, enhancing the effectiveness of cooling fans by utilizing the fins to direct the air flow through the interior of the enclosure to cool the enclosed components. A system having existing air flow can be harvested without impacting the systems energy consumption. Air flow across the enclosure can drive cool air into the enclosure and evacuate hot air from the enclosure cavity improving thermal performance. Aspects and implementations of the present disclosure can decrease overall drive cost by providing more efficient and inexpensive thermal management.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. The host system 120 can include a processor chipset and a software stack executed by the processor chipset. The processor chipset can include one or more cores, one or more caches, a memory controller (e.g., an SSD controller), and a storage protocol controller (e.g., PCIe controller, SATA controller, CXL controller). The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1 illustrates memory sub-system 110 as an example. In general, the host system 120 can access multiple memory sub-systems via a same communication connection, multiple separate communication connections, and/or a combination of communication connections. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

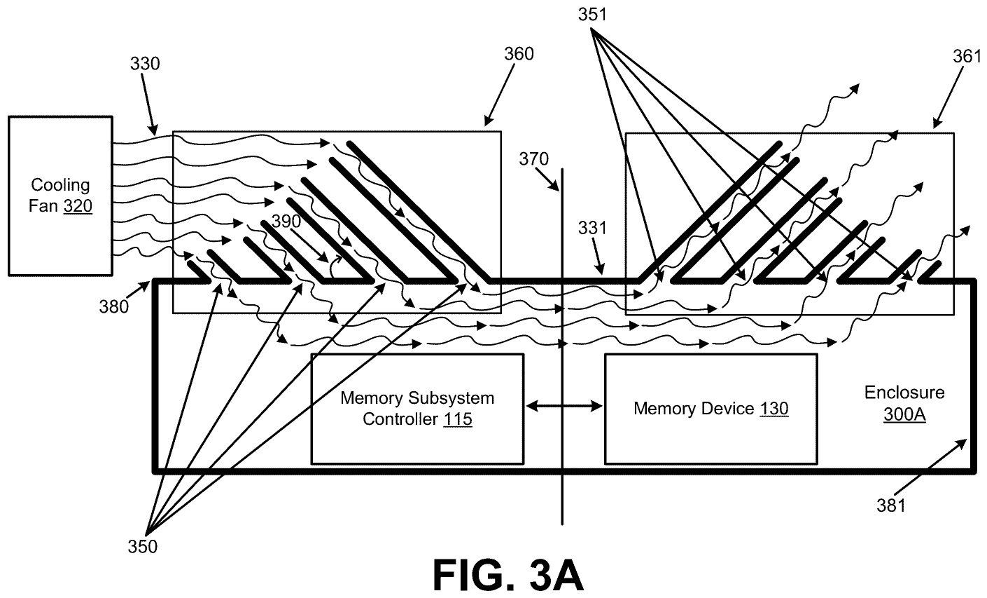

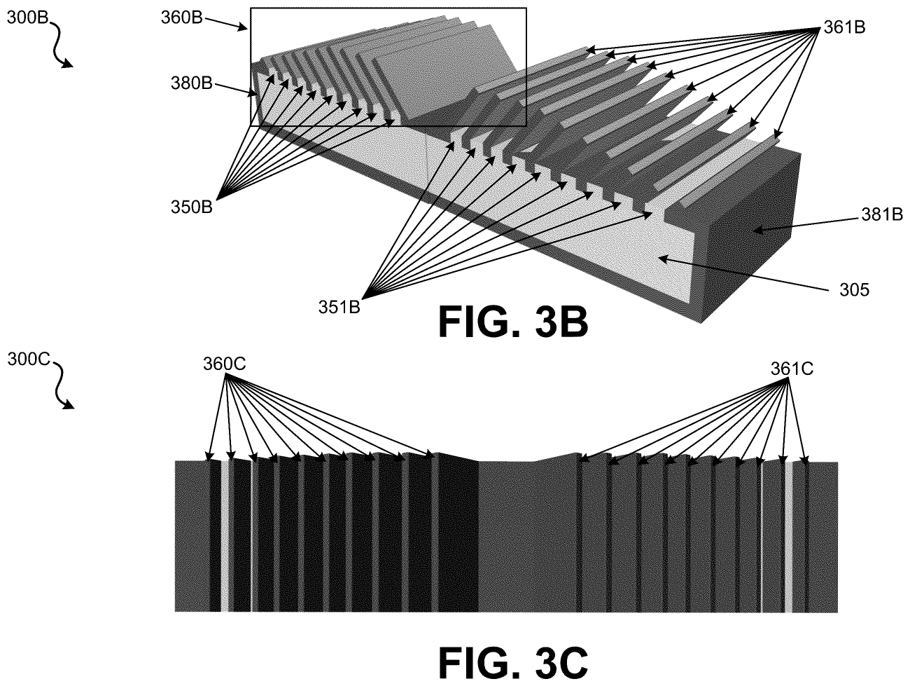

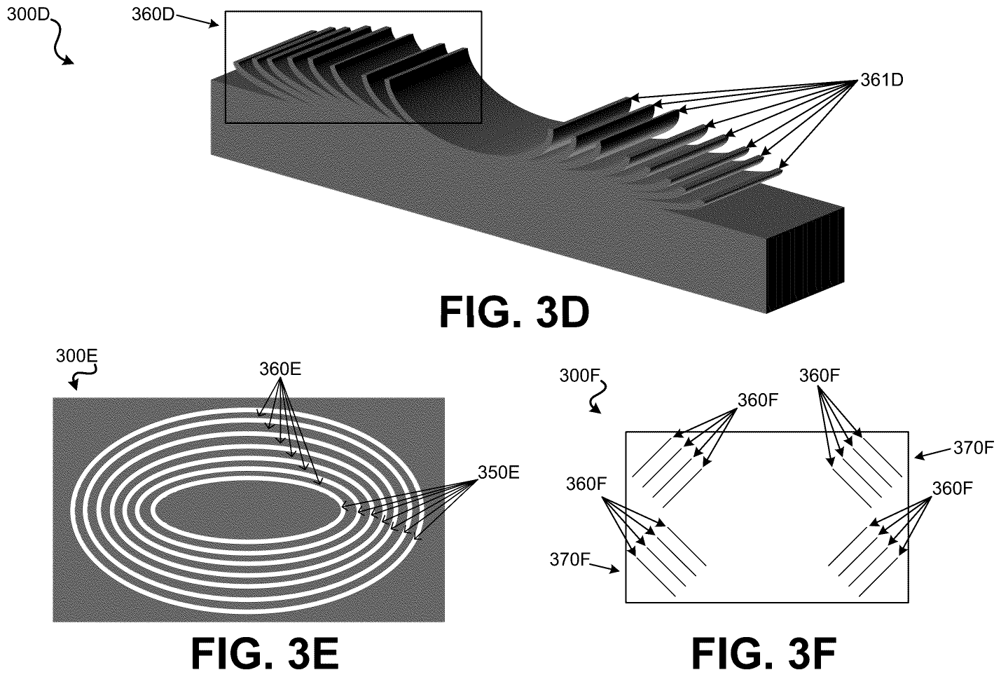

In one embodiment, the memory sub-system 110 is enclosed in an enclosure 113 for passive thermal cooling, thereby eliminating the need for TIMs. Enclosure 113 can have openings for increased air flow and fins affixed to the exterior surface of the enclosure that direct air flow through the interior of the enclosure to cool the enclosed components (e.g., memory sub-system 110). Each fin can be disposed adjacent to at least one of the openings, as shown in more detail in FIG. 3A. The fins can be arranged to circulate fluid flow (e.g., air flow) through the interior of the enclosure in order to cool the components of memory sub-system 110 or other circuit components contained within enclosure 113. The enclosure can be mounted on a rackmount server chassis of a rackmount server. The rackmount server can be slid into a server rack. Cooling fans can be mounted to the rackmount server chassis and/or to the server rack to provide air flow to the enclosure. The air flow provided by the cooling fans can be directed by the fins through the interior of the enclosure to cool the enclosed components (e.g., memory sub-system 110) utilizing existing system air flow provided be fans for cooling. Although FIG. 1 illustrates enclosure 113 as enclosing memory sub-system 110, it should be understood that in other embodiments, enclosure 113 can be used to enclose any other type of circuit components.

In some embodiments, fins may be other directional air flow guides and can be at least one of many different designs. For example, curved fins, straight fins, lipped fins, concentrical ovals, pin fins, staggered fins, etc. or any combination thereof. Fins or other directional air flow guides can be disposed on one or more surfaces of enclosure 113. Fins are to direct the air into openings (e.g., slots, holes, or other apertures) to allow for passive air transfer. The openings can be a counter measure to the propensity of enclosures to create an electromagnetic interference (EMI) shield (“faraday cage”). Further details with regards to the operations and functionality of enclosure 113 are described below.

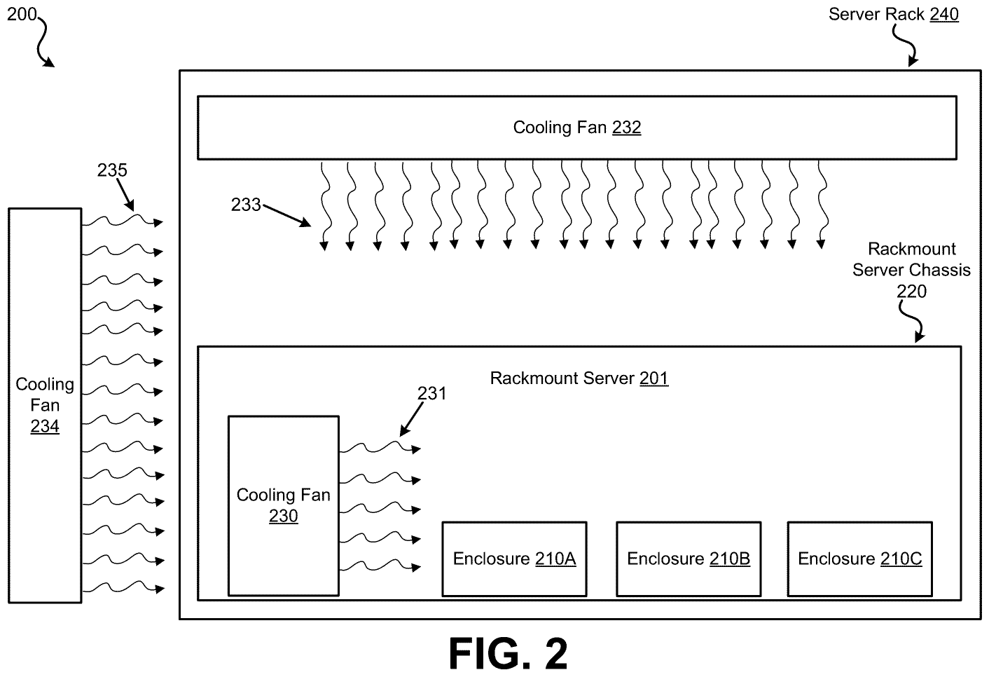

FIG. 2 illustrates an example rackmount server system 200 (system 200) that includes enclosures 210A-C in accordance with some embodiments of the present disclosure.

Rackmount server system 200 can include a rackmount server 201. Rackmount server 201 can be mounted in a standardized rack (e.g., server rack 240), for enhanced space utilization and simplified cable management. Rackmount server 201, can include components such as processors, memory, storage drives, and networking hardware mounted to and housed in a rackmount server chassis (e.g., rackmount server chassis 220).

In some embodiments, rackmount server 201 includes a rackmount server chassis 220. In data centers, rackmount server chassis 220 can be designed for efficient space utilization. Rackmount server chassis 220 can conform to standardized dimensions and form factors (e.g., the Electronic Industries Alliance (EIA) specifications) that help to ensure compatibility in server rack systems. For example, a rackmount server chassis can conform to certain form factors, such as 1 U, 2 U, or 4 U, indicating the height of the rackmount server in rack units (1 U equals approximately 1.75 inches). Rackmount server chassis 220 can be designed to house components such as motherboards, power supplies, hard drives, PCBAs, and cooling systems, all within the compact and modular framework of the rackmount server chassis. Standardized dimensions and form factors of rackmount server chassis can facilitate streamlined installation and maintenance of rackmount servers in server racks and also ensures robust physical protection.

Rackmount server 201 includes enclosures 210A, 210B, and 210C. Enclosures 210A-C can be mounted on rackmount server chassis 220 of rackmount server 201. Enclosures 210A-C can enclose components. For example, enclosure 210A can enclose memory subsystem 110 of FIG. 1. In some embodiments, rackmount server 201 is not limited to enclosures 210A, 210B, and 210C, but can include additional enclosures or fewer enclosures. In some embodiments, rackmount server 201 can include additional enclosures, such as 210D, 210E, 210F, and so forth. Rackmount server 201 can house a wide array of components and/or enclosures as needed for the particular use case.

Cooling fan 230 can be mounted on rackmount server chassis 220 of rackmount server 201. The layout of rackmount servers 201 can facilitate efficient heat dissipation and air flow management. For example, cooling fan 230 can be placed so that air flow 231 generated by cooling fan 230 is directed towards enclosures 210A-C.

In some embodiments, rackmount server system 200 can include a server rack 240. Server rack 240 can hold rackmount servers (e.g., rackmount server 201). Rackmount servers (e.g., rackmount server 201) slide into slots within server rack 240, aligning with a standardized spacing for organization and accessibility. A server rack can be, for example 19 inches wide, and can support various server sizes, securely holding them in place. In some embodiments, server rack 240 can include cooling fan 232. In some embodiments, cooling fan 232 can be a rackmount cooling fan that is slid into a rack slot of server rack 240. In some embodiments, cooling fan 232 can be placed so that air flow 233 generated by cooling fan 232 is directed towards enclosures 110A-C. In some embodiments, server rack 240 can include cooling fan 234. In some embodiments, cooling fan 234 can be a cooling fan that is a part of server rack 240. In some embodiments, cooling fan 234 can be placed so that air flow 235 generated by cooling fan 234 is directed towards enclosures 210A-C.

In some embodiments, cooling fans (e.g., cooling fans 230, 232, 234) can provide fluid flow (air flow) to enclosures 210A-C. Fins of enclosures 210A-C can be arranged to circulate fluid flow through the interiors of enclosures 210A-C. For example, the openings can be in an exterior surface of the enclosures 210A-C. The fins can extend from the exterior surface at an angle relative to the exterior surface. The angle relative to the exterior surface can be adjusted so that the fins direct more air flow into the interior of enclosures 210A-C. For example, in some embodiments, the angle can be between 15° and 60°.

In some embodiments, the exterior surface can be a top surface of the enclosure. In some embodiments, the exterior surface can be a lateral surface (e.g., side surface) of the enclosure. The openings can be in any surface of the enclosure that allows air flow to be directed into the openings by the fins. Similarly, the fins can be affixed to any surface of the enclosure that allows air flow to be directed into the openings by the fins. In some embodiments, the fins can be affixed to any exterior surface that allows the fans too most effectively cool the enclosure and enclosed components. This can be dependent on the position of the fans, the position of the enclosure relative to the fans, the position of the enclosed components in the enclosure, etc.

In some embodiments, enclosures 210A-C can harvest existing air flow from fans already included by default in a system (e.g., a rackmount server system). Enclosures 210A-C funnel the existing system exhaust (air flow) into and out of the enclosures recycling the stagnate air improving thermal performance.

In some embodiments, enclosures 210A-C are coupled to rackmount server chassis 220 to enclose a set of memory storage devices within an interior of each the enclosures of the set of enclosures 210A-C. A cooling fan 230 can coupled to rackmount server chassis 220. Cooling fan 230 provides fluid flow (air flow 231) to enclosures 210A-C. In some embodiments, a cooling fan (e.g., cooling fan 232 or 234) is coupled to server rack 240.

In some embodiments, each enclosure of enclosures 210A-C includes a set of openings exposing at least a portion of the interior of each enclosure of enclosures 210A-C to an environment outside the set of enclosures 210A-C. In some embodiments, each opening of the set of openings is in a top exterior surface of each enclosure of the set of enclosures and each fin of the set of fins extends from the top exterior surface at an angle relative to the top exterior surface. Each enclosure of enclosures 210A-C further includes a set of fins affixed to an exterior surface of each enclosure of enclosures 210A-C. Each fin of the set of fins is disposed adjacent to at least one of the openings of the set of openings.

In some embodiments, each opening of the set of openings can be in any exterior surface of each enclosure of the set of enclosures and each fin of the set of fins extends from the exterior surface at an angle relative to the exterior surface. Each enclosure of enclosures 210A-C further includes a set of fins affixed to the exterior surface of each enclosure of enclosures 210A-C. Each fin of the set of fins can be disposed adjacent to at least one of the openings of the set of openings. In some embodiments, openings of the set of openings can be in multiple exterior surfaces of the enclosure and fins of the sets of fins can be affixed to the multiple exterior surfaces of each enclosure of enclosures 210A-C. For example, an enclosure may have three openings, two of the openings being in a top exterior surface of the enclosure and one opening being in a side exterior surface of the enclosure. The enclosure may have six fins, four of the fins being affixed to the top exterior surface of the enclosure and two of the fins being affixed to the side exterior surface of the enclosure.

In some embodiments, at least one of the openings of the set of openings is disposed between at least two fins of the set of fins. The set of fins can be arranged to circulate fluid flow through the interior of each enclosure of enclosures 210A-C. In some embodiments, the set of fins varies in length and is arranged such that at least one fin nearer to a center of each of the exterior surfaces of the enclosure (e.g., enclosures 210A-C) is longer than at least one fin nearer to an edge of the exterior surface of the enclosure.

In some embodiments, the sets of fins can be fins or other directional air flow guides and can be at least one of many different designs. For example, straight fins, lipped fins, concentrical ovals, pin fins, staggered fins, etc. The sets of fins or other directional air flow guides can be disposed on one or more surfaces of the enclosure. The sets of fins are to direct the air into sets of openings (e.g., slots, holes, or other apertures) to allow for passive air transfer. The openings can be a counter measure to the propensity of enclosures to create an electromagnetic interference (EMI) shield (“faraday cage”).

In some embodiments, rackmount servers (e.g., rackmount server 201) and server rack 240 can be part of a data center. Data-intensive applications (e.g., such as artificial intelligence (AI) and the metaverse) can cause data centers to be increasingly subjected to heavy computing demands. These applications can generate substantial heat, necessitating more effective thermal management solutions. The cooling capabilities of the present disclosure can be used to help maintain optimal efficiency and avoid overheating risks for servers and server racks deployed in data centers.

FIG. 3A illustrates an enclosure 300A in accordance with some embodiments of the present disclosure.

In some embodiments, enclosure 300A includes sets of openings 350 and 351 for increased air flow. Enclosure 300A includes set of fins 360 affixed to an exterior surface 331 of enclosure 300A that direct air flow 330 (e.g., from cooling fan 320) through an interior of enclosure 300A. Each fin of set of fins 360 can be disposed adjacent to an opening of set of openings 350 to channel air flow 330 into the opening. Cooling fan 320 can be mounted to a rackmount server chassis and/or to a server rack and can be positioned to provide air flow to enclosure 300A. Set of fins 361 can be arranged to direct air flow 330 out of enclosure 300A providing circulation of air within enclosure 300A (e.g., reducing stagnate air). Air flow 330 provided by cooling fan 320 can be directed by sets of fins 360 and 361 through the interior of enclosure 300A to cool enclosed components. For example, enclosure 300A can enclose a memory sub-system that includes a memory device 130 and a memory sub-system controller 115 communicably coupled to memory device 130. In some embodiments, enclosure 300A can enclose a PCBA.

In some embodiments, the openings can be in multiple exterior surfaces of enclosure 300A and the fins can be affixed to multiple exterior surfaces of enclosure 300A. For example, enclosure 300A may have four openings, three of the openings being in a top exterior surface of enclosure 300A and one opening being in a side exterior surface of enclosure 300A. Enclosure 300A may have eight fins, six of the fins being affixed to the top exterior surface of enclosure 300A and two of the fins being affixed to the side exterior surface of enclosure 300A. In some embodiments, the openings can be in and the fins can be affixed to any combination of exterior surfaces of enclosure 300A that effectively allows for airflow to circulate through the enclosure to cool the enclosed components.

In some embodiments, sets of fins 360 and 361 vary in length and are arranged such that at least one fin nearer to a center 370 of the exterior surface 331 of enclosure 300A is longer than at least one fin nearer to an edge (e.g., edges 380 and 381) of exterior surface 331 of enclosure 300A. Sets of fins 360 and 361 can a chevron fin, a straight blade fin, an elliptical fin, a louvered fin, and/or the like.

In some embodiments, an apparatus includes enclosure 300A to enclose a memory sub-system within an interior of enclosure 300A. The memory sub-system includes memory device 130 and memory sub-system controller 115 communicably coupled to memory device 130.

Enclosure 300A includes sets of openings 350 and 351 exposing a portion of the interior of enclosure 300A to an environment outside enclosure 300A. Sets of fins 360 and 361 are affixed to an exterior surface 331 of enclosure 300A. Each fin of sets of fins 360 and 361 can be adjacent to at least one of the openings of sets of openings 350 and 351. At least one of the openings of sets of openings 350 and 351 can be disposed between at least two fins of sets of fins 360 and 361. Sets of fins 360 and 361 can be arranged to circulate fluid flow (e.g., air flow 330 generated by cooling fan 320) through the interior of enclosure 300A. For example, fins 360 can be positioned and arranged so that air flow 330 is directed into the interior of enclosure 300A via openings 350. Air flow 330 can be used as a coolant medium. Memory subsystem 115 and memory device 130 transfer heat to air flow 330. Fins 361 can be positioned and arranged so that air flow 330 is directed out of the interior of enclosure 300A via openings 351. The heat transferred to air flow 330 is removed from enclosure 300A as air flow 330 leaves the interior of enclosure 300A.

In some embodiments, the sets of fins 360 and 361 vary in length and are arranged such that at least one fin nearer to a center 370 of exterior surface 331 of enclosure 300A is longer than at least one fin nearer to an edge (e.g., edge 380 or edge 381) of exterior surface 331 of enclosure 300A. Each opening of sets of openings 350 and 351 is in exterior surface 331 of enclosure 300A. Each fin of the sets of fins can extend from exterior surface 331 at an angle (e.g., angle 390) relative to exterior surface 331. For example, in some embodiments, angle 390 can be between 15° and 60°.

In some embodiments, exterior surface 331 of enclosure 300A is a top exterior surface. Exterior surface 331 of enclosure 300A can be a side exterior surface, a front exterior surface, a back exterior surface, etc. Sets of fins can be disposed on any of a top exterior surface, a side exterior surface, a front exterior surface, a back exterior surface, etc. In some embodiments, each of fin of sets of fins 360 and 361 can be at least one of a chevron fin, a straight blade fin, an elliptical fin, a louvered fin, or the like.

In some embodiments, enclosure 300A is not made of a conductive medium and sets of fins 360 and 361 do not function as heat sinks. However, in some embodiments, enclosure 300A may be made of metal and sets of fins 360 and 361 can function as heat sinks. In such a case, enclosure 300A can be made of a conductive medium. In some embodiments, a plastic type enclosure 300A may be impregnated with higher conductivity fillers. In some embodiments, enclosure 300A can be metal, plastic, or another multi-constituent composite material, designed to enhance thermal conductivity. For example, composite materials may include thermally conductive fillers, such as, alumina oxide, boron nitride, graphite, carbon fibers, carbon nanotubes, silver flakes, copper particles, aluminum nitride, silicon carbide, etc. These composite materials may facilitate heat dissipation.

In some embodiments, enclosure 300A can have dimensions and form factors that conform to an established standard. For example, enclosure 300A can meet the specifications set by standards such as the Storage Networking Industry Association (SNIA) SSD form factor standard, the National Electrical Manufacturers Association (NEMA) enclosure rating, the Electronic Industries Alliance/Telecommunications Industry Association (EIA/TIA) standards for telecommunications equipment, the Advanced Technology extended (ATX) form factor standard, the Micro-ATX form factor standard, Serial ATA International Organization (SATA-IO) standards (e.g., U.2 standard), Peripheral Component Interconnect Special Interest Group (PCI-SIG) standards (e.g., M.2 standard), Institute of Electrical and Electronics Engineers (IEEE) standards, and/or the like. In some embodiments, enclosure 300A can conform to any necessary standard, ensuring compatibility within varied systems (e.g., data centers, consumer electronics, etc.).

FIG. 3B illustrates a perspective view of an enclosure 300B in accordance with some embodiments of the present disclosure. FIG. 3B presents a perspective view of enclosure 300B, the same or similar in structure to those enclosures shown and described in FIGS. 1-3A.

In some embodiments, enclosure 300B includes sets of openings 350B and 351B for increased air flow. Enclosure 300B includes set of fins 360B affixed to an exterior surface of enclosure 300B. Sets of fins 360B direct air flow through an interior 305 of enclosure 300B. Each fin of set of fins 360B can be disposed adjacent to an opening of set of openings 350B to channel air flow into or out of the opening. Set of fins 361B can be arranged to direct air flow into or out of enclosure 300B providing circulation of air within enclosure 300B (e.g., reducing stagnate air). Air flow can be directed by sets of fins 360B and 361B through interior 305 of enclosure 300B to cool enclosed components. For example, enclosure 300B can enclose a memory sub-system that includes a memory device and a memory sub-system controller communicably coupled to memory device.

In some embodiments, sets of fins 360B and 361B vary in length and are arranged such that at least one fin nearer to a center of the exterior surface of enclosure 300B is longer than at least one fin nearer to an edge (e.g., edges 380B and 381B) of the exterior surface of enclosure 300B. Sets of fins 360B and 361B can be one of chevron fins, straight blade fins, elliptical fins, louvered fins, or the like.

FIG. 3C illustrates a top view of an enclosure 300C in accordance with some embodiments of the present disclosure. FIG. 3C presents a perspective view of enclosure 300C, the same or similar in structure to enclosures shown and described in FIGS. 1-3A.

In some embodiments, enclosure 300C includes sets of openings for increased air flow. Enclosure 300C includes sets of fins 360C and 361C affixed to an exterior surface of enclosure 300C. Sets of fins 360C and 361C direct air flow through an interior of enclosure 300C. Each fin of sets of fins 360C and 361C can be disposed adjacent to an opening of set of openings to channel air flow into or out of the opening.

FIG. 3D illustrates a perspective of an enclosure in accordance with some embodiments of the present disclosure.

In some embodiments, enclosure 300D includes sets of fins 360D and 361D affixed to an exterior surface of enclosure 300D. Sets of fins 360D and 361D direct air flow through an interior of enclosure 300D. Each fin of sets of fins 360D and 361D can be disposed adjacent to an opening of set of openings in the exterior surface of enclosure 300D to channel air flow into or out of the opening. In some embodiments, sets of fins 360D and 361D can be curved fins.

FIG. 3E illustrates top view of an enclosure in accordance with some embodiments of the present disclosure.

In some embodiments, enclosure 300E includes openings 350E for increased air flow. Enclosure 300E includes fins 360E affixed to an exterior surface of enclosure 300E. Fins 360E direct air flow through an interior of enclosure 300E. Each fin or fins 360E can be disposed adjacent to an opening of openings 350E to channel air flow into or out of the opening. In some embodiments, fins 360E can be substantially circular or oval in shape. In some embodiments, openings 350E can be substantially circular or oval in shape.

FIG. 3F illustrates top view of an enclosure in accordance with some embodiments of the present disclosure.

In some embodiments, enclosure 300F includes fins 360F affixed to an exterior surface of enclosure 300F. Fins 360F direct air flow through an interior of enclosure 300F. Each fin of fins 360F can be disposed adjacent to an opening of a set of openings in the exterior surface of enclosure 300F to channel air flow into or out of the opening. In some embodiments, fins 360F can be set at various angles with respect to edges 370F of the exterior surface of enclosure 300F.

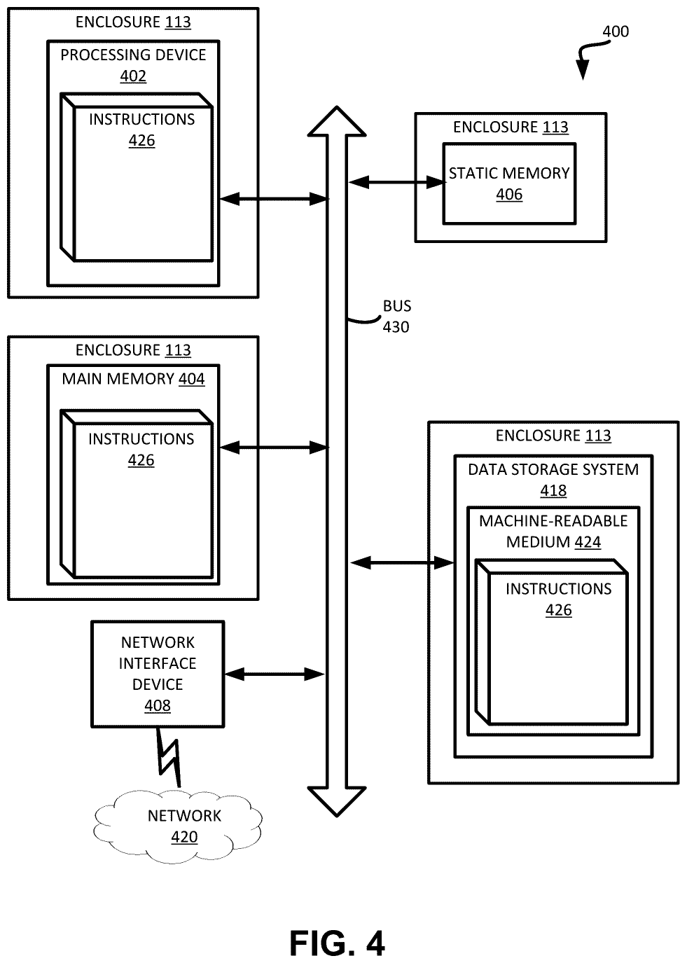

FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the local media controller 135 and/or memory subsystem controller 115 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or RDRAM, etc.), a static memory 406 (e.g., flash memory, static random access memory (SRAM), etc.), and a data storage system 418, which communicate with each other via a bus 430. In some embodiments, at least one of processing device 402, main memory 404, static memory 406, or data storage system 418 are enclosed in an enclosure (e.g., enclosure 113 of FIG. 1) for passive thermal cooling.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to a controller (e.g., local media controller 135 and/or memory subsystem controller 115 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus comprising:
an enclosure to enclose a memory sub-system within an interior of the enclosure, the memory sub-system comprising a memory device and a memory sub-system controller communicably coupled to the memory device, wherein the enclosure comprises:
a plurality of openings exposing at least a portion of the interior of the enclosure to an environment outside the enclosure; and
a plurality of fins affixed to an exterior surface of the enclosure, wherein each fin of the plurality of fins is disposed adjacent to at least one of the openings of the plurality of openings.

2. The apparatus of claim 1, wherein at least one of the openings of the plurality of openings is disposed between at least two fins of the plurality of fins.

3. The apparatus of claim 2, and wherein the plurality of fins is arranged to circulate fluid flow through the interior of the enclosure.

4. The apparatus of claim 1, wherein the plurality of fins varies in length and is arranged such that at least one fin nearer to a center of the exterior surface of the enclosure longer than at least one fin nearer to an edge of the exterior surface of the enclosure.

5. The apparatus of claim 1, wherein each opening of the plurality of openings is in an exterior surface of the enclosure, and wherein each fin of the plurality of fins extends from the exterior surface at an angle relative to the exterior surface.

6. The apparatus of claim 5, wherein the exterior surface of the enclosure is a top exterior surface.

7. The apparatus of claim 1, wherein each of fins of the plurality of fins is at least one of a chevron fin, a straight blade fin, an elliptical fin, or a louvered fin.

8. An enclosure for a printed circuit board assembly (PCBA) comprising:
a plurality of openings exposing at least a portion of an interior of the enclosure to an environment outside the enclosure; and
a plurality of fins affixed to an exterior surface of the enclosure, wherein each fin of the plurality of fins is disposed adjacent to at least one of the openings of the plurality of openings.

9. The enclosure for the PCBA of claim 8, wherein at least one of the openings of the plurality of openings is disposed between at least two fins of the plurality of fins.

10. The enclosure for the PCBA of claim 8, wherein the plurality of fins is arranged to circulate fluid flow through the interior of the enclosure.

11. The enclosure for the PCBA of claim 8, wherein the plurality of fins varies in length and is arranged such that at least one fin nearer to a center of the exterior surface of the enclosure is longer than at least one fin nearer to an edge of the exterior surface of the enclosure.

12. The enclosure for the PCBA of claim 8, wherein each opening of the plurality of openings is in an exterior surface of the enclosure, and wherein each fin of the plurality of fins extends from the exterior surface at an angle relative to the exterior surface.

13. The enclosure for the PCBA of claim 12, wherein each fin of the plurality of fins extends from the exterior surface at an angle relative to the exterior surface.

14. The enclosure for the PCBA of claim 8, wherein each of fins of the plurality of fins is at least one of a chevron fin, a straight blade fin, an elliptical fin, or a louvered fin.

15. A system comprising:
a rackmount server chassis;
a plurality of enclosures coupled to the rackmount server chassis to enclose a plurality of memory storage devices within an interior of each of the enclosures of the plurality of enclosures;
a cooling fan coupled to the rackmount server chassis, wherein the cooling fan provides fluid flow to the plurality of enclosures, and wherein each enclosure of the plurality of enclosures comprises:
a plurality of openings exposing at least a portion of the interior of each enclosure of the plurality of enclosures to an environment outside the plurality of enclosures; and
a plurality of fins affixed to an exterior surface of each enclosure of the plurality of enclosures, wherein each fin of the plurality of fins is disposed adjacent to at least one of the openings of the plurality of openings.

16. The system of claim 15, further comprising a server rack, wherein the cooling fan is coupled to the server rack.

17. The system of claim 15, wherein at least one of the openings of the plurality of openings is disposed between at least two fins of the plurality of fins.

18. The system of claim 17, wherein the plurality of fins is arranged to circulate fluid flow through the interior of each enclosure of the plurality of enclosures.

19. The system of claim 15, wherein the plurality of fins varies in length and is arranged such that at least one fin nearer to a center of the exterior surface of the plurality of enclosures is longer than at least one fin nearer to an edge of the exterior surface of the plurality of enclosures.

20. The system of claim 15, wherein each fin of the plurality of fins extends from the exterior surface at an angle relative to the exterior surface.
